(19) United States
(12) Patent Application Publication
(10) Pub. No.: US 2006/0100094 A1
(43) Pub. Date: May 11, 2006

(54) Method and apparatus for manufacturing a catalyst

(75) Inventors: Gosse Boxhoorn, Wijnandsrade (NL); Martin Dinant Bijker, Helmond (NL); Marinus Franciscus J. Evers, Heeze (NL); Franciscus Cornelius Dings, Veldhoven (NL)

Correspondence Address: PILLSBURY WINTHROP SHAW PITTMAN, LLP, P.O. BOX 10500, MCLEAN, VA, 22102, US

(73) Assignee: OTB Group B.V., Eindhoven (NL)

(21) Appl. No.: 10/518,695

(22) PCT Filed: Jun. 23, 2003
(86) PCT No.: PCT/NL03/00462

§ 371 Date: Sep. 20, 2005

(30) Foreign Application Priority Data
Jun. 21, 2002 (NL) 1020923

(51) Int. Cl. B01J 21/18; C23C 14/32; C23C 14/00

(52) U.S. Cl. 502/185; 502/180; 502/327; 204/298.2; 204/192.1

(57) ABSTRACT

A method for manufacturing a catalyst, wherein a substrate (I) is introduced into a processing chamber (2, 102); wherein at least one plasma (P) is generated by at least one plasma cascade source (3, 103); wherein at least one deposition material (A, B) is deposited on the substrate (1, 101) under the influence of the plasma (P). The invention further provides an apparatus for manufacturing a catalyst, the apparatus being provided with at least one plasma cascade source (3, 103) for generating at least one plasma (P), the apparatus comprising means for bringing deposition material (A, B) into each plasma (P), the apparatus being further provided with substrate positioning means (8, 118) to bring and/or keep at least a part of a substrate (1, 101) in such a position in a processing chamber (2, 102) that the substrate (1, 101) makes contact with the plasma (P).

The invention relates to a method according to the preamble of claim 1.

The invention also relates to an apparatus according to the preamble of claim 34.

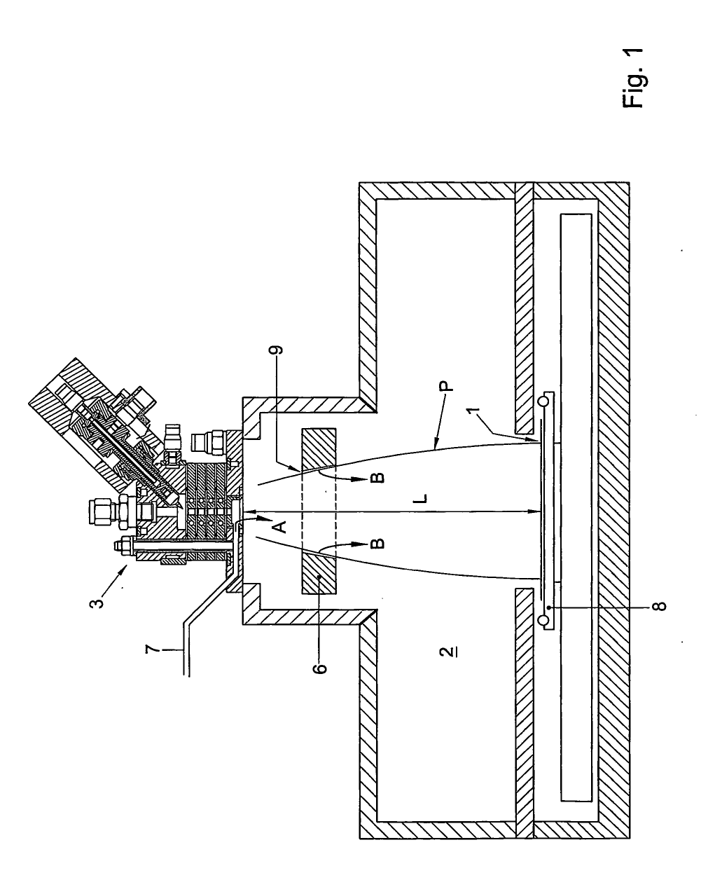

Such a method and apparatus are known from DE 196 10 015. DE-A-196 10 015 describes a method and an apparatus for applying ceramic layers. According to the method of this patent application, no fewer than twenty plasma sources are required to cover a reasonable surface with the desired layer. The noise produced by these twenty plasma sources is an additional drawback of the invention described in the laid-open patent application DE 196 10 015 of Hoechst A. G. The twenty plasma sources are shown in FIG. 1 of the laid-open patent application DE 196 10 015 of Hoechst A. G. According to column 3, line 27 to column 4, line 10, the material to be applied on the substrate is supplied as solid particles to the plasma through a narrow pipe. It will be clear that a very regular supply of solid particles to the plasma is difficult to realize in this manner.

The publication does not disclose that the known method and apparatus can be used for manufacturing a catalyst.

A method for manufacturing a catalyst is known from practice, where catalyst material is used which, possibly after an activation treatment, such as a thermal treatment and/or reducing step, is catalytically active. Such an activation treatment can for instance be carried out after the catalyst material has been applied to substrates. The thermal treatment referred to is used, for instance, to convert finely divided metal oxides into catalytically active finely divided metals.

In general, catalysts are used as solid shaped bodies having dimensions of a few mm's or as particles of dimensions varying from about 300 to less than 10 μm. It is possible to shape the catalyst material as such into (porous) bodies or particles. Examples are the catalysts based on iron oxide for the dehydrogenation of ethyl benzene to styrene and for the carbon monoxide shift conversion reaction. Raney metals, of which Raney nickel is the most well-known, are an example of small particles that consist substantially of the catalytically active material. Raney nickel consists of porous particles having dimensions of 10 to 20 μm.

Mostly, however, with solid catalysts, so-called carriers are used. A carrier is a high-porous, thermostable material on which one or more catalytically active components have been provided, if possible finely divided. The carrier stabilizes the shape, dimensions and the porous structure of the catalytically active bodies or particles. Also, a carrier prevents a rapid decrease of the catalytically active surface as a result of sintering of the active particles during the thermal pretreatment and/or the catalytic reaction.

The most common carrier is aluminum oxide, which is commercially available in a large variety of shaped bodies and powders having surface areas of less than 1 m² per gram to more than 500 m² per gram. Another known carrier material is silicon dioxide, which is also commercially available in all kinds of shapes. Also, activated carbon is often used as a carrier material.

Catalysts are used in the form of a fixed catalyst bed, whereby a flow of reactants is passed through a bed of catalyst bodies. Because the pressure drop should not be too high, catalyst bodies must be used that are not too small. Evidently, in that case, strict requirements will also be imposed on the mechanical strength of catalyst bodies. When filling a catalyst reactor, catalyst bodies should not pulverize. Another implementation of a catalyst bed is the fluidized bed. In that case, a flow of reactants is passed through a bed of relatively small catalyst particles. The friction of the flow of reactants is now greater than or equal to the weight of the catalyst bed. As a result, the catalyst bed expands and the catalyst particles are set into a more or less vehement motion. The relatively small catalyst particles of a fluidized bed do not entail any problems of transport limitations of reactants and reaction production. On the other hand, a fluidized bed can never yield a complete conversion, and very stringent requirements are to be imposed on the wear resistance of the catalyst particles.

Another form in which catalysts are typically applied is as a suspension of relatively small catalyst particles in a liquid. Upon completion of the reaction, the catalyst must be separated from the liquid through filtration or centrifugation. In this regard, relatively heavy catalyst particles are favorable: the catalyst can then be separated from the liquid through settlement. It will be clear that in this case too, the wear resistance of the catalysts must meet high requirements. If the catalyst particles become too small, they can no longer be readily separated from the reaction products. In general, the occurrence of catalyst particles in the reaction product is unallowable. First of all, a contamination of the reaction product with the catalyst is nearly always undesired. In the production of medicines or ingredients of foods, this is in most cases even entirely unacceptable. Many precious metals are used as catalysts. It will be clear that a loss of precious metal, given the high price, is economically unallowable.

From practice, it is known to apply a catalytically active material as a more or less porous layer to a solid, non-porous substrate. This method can have many advantages, for instance in the catalytic cleaning of exhaust gases of motor vehicles. In this case, the pressure drop across the catalyst bed must be low and the catalyst bodies should not pulverize as a result of the shaking of the vehicle. Therefore, often use is made of so-called monoliths. These are shaped cylindrical bodies of a thermostable ceramic material, within which a honeycomb structure of a large number of narrow straight channels are present. The catalytically active material is applied to the walls of the channels of the monolith. For use, the monoliths are normally provided in a catalyst reactor. Although the production of these monoliths has been perfected to a high degree and the mechanical and thermal stability has been raised high, such bodies still have drawbacks. For instance, the thermal conductivity of the ceramic monoliths is relatively low. Also, the thermal contact of the monolith with the metallic housing is poor. As a result, the temperature of such a catalyst can run up very high during fast rides over motorways. A high temperature leads to deactivation of the catalyst. Furthermore, providing the catalytically active material in the narrow channels of the monoliths is cumbersome. In this connection, use is made of robots, which soak the monolith in a suspension of the catalytically active material. After this, the excess of the impregnated material must be blown out of the channels with compressed air. In certain cases, it is necessary to soak in the suspension of the catalytically active material more than once. Soaking monoliths in a suspension of catalyst particles can be employed only with monoliths of relatively small length, about 30 cm. In case of a greater length, the thickness of the layer of catalyst applied will vary too much.

A solution to a number of these problems is to make use of a corrugated metal or alloy in the form of a thin sheet. To this metal, the catalytically active layer can be applied, after which the sheet can be rolled up and be fixated in rolled-up form. The result is a cylinder having a large number of channels of very small dimensions. Because the thermal conductivity of metals is relatively high, heat can be removed relatively easily. When the cylinder is connected to the wall of the reactor by welding or soldering, the thermal conductivity becomes much higher.

Also within the chemical industry, thin shaped metal sheets are used. The reactor packings developed by the Swiss firm of Sulzer are a good example in point. To mix two liquid flows, or to bring a liquid flow in an intimate contact with a gas flow, Sulzer has developed structures of folded metal tin which are uncommonly effective as static mixers. Accordingly, distillation columns, where an intimate contact between the gas flow and the liquid flow is important, constitute a main area of application of such packings.

It will be clear that applying a catalytically active layer to the surface of such a static mixer can have major technical advantages. A very good contact is accomplished between a liquid and/or gas stream and the catalyst, and the necessity of removing the catalyst after the reaction through filtration or centrifugation is eliminated. Another advantage is that the catalyst, after it has been deactivated by a thermal treatment, can be regenerated in the reactor with a gas stream, for instance with a hydrogen stream, which is technically extremely attractive. With the small particles in which conventional catalysts are used, suspended in liquids, this is not possible because of the high pressure drop. Moreover, use can be made of the heat conductivity of the metal structures by bringing these into proper thermal contact with the wall of the reactor.

As already mentioned, applying catalyst layers to non-porous, solid metal surfaces is known. Especially in the case of catalysts for the purification of exhaust gases of car engines, the above-mentioned rolled-up corrugated metal sheets are used for the more expensive catalyst bodies. On these sheets, a catalytically active material has been provided. In general, it is cumbersome to effect a proper adhesion of a catalytically active material to a metal surface. According to the state of the art, the starting point is an alloy which contains a relatively high content of aluminum, such as Fecralloy or Kanthaal. Upon maintaining such an alloy at an elevated temperature in an oxygen containing gas atmosphere, aluminum oxide crystallites grow on the metal surface, which are intimately bonded to the alloy surface. The carrier materials of exhaust gas catalyst, this is mostly aluminum oxide, bond reasonably to the aluminum oxide crystallites that have grown out of the alloy surface.

According to a first method of the prior art, the catalyst particles are applied by dipping the thermally pretreated corrugated sheets in a suspension of the catalyst. Because the length of the cylinders formed from the corrugated sheets is not great in the case of exhaust gas catalysts, no great differences in thickness of the catalyst layer upon vertical dripping and drying will be observed.

In other applications than exhaust gas catalysts, the length of the channels in the structure will be greater. In that case, soaling and dripping will lead to an unacceptably large difference in thickness of the layer that contains the catalytically active material. Therefore, a suspension of the catalyst is sometimes sprayed onto the horizontally disposed corrugated sheets. In that case, however, it is also cumbersome to prevent the formation of a thicker layer in the lower part of the corrugations.

It has also been proposed to apply the catalytically active porous layer through electrophoresis of suspended catalyst particles. In general, suspended solids particles have an electrostatic charge. This electrostatic charge is neutralized by counter ions present in the liquid layer around the particles. Mostly, a part of the layer of counter ions is present in the liquid layer that does not move along with the particles. The interface that separates the mobile part of the twin layer from the non-mobile part is known as the hydrodynamic shear plane. Now, when an electrostatic field is applied within a suspension of such particles, the particles will start to move. In this way, solids particles can be applied to a conductive surface. The setting of the concentration of the suspended catalyst particles in the suspension used in the electrophoresis is cumbersome. The viscosity of the suspension should not become too high, while the solid particles should not settle fast.

An advantage of the above-mentioned procedures according to the prior art is that the starting point can be commercial catalysts. These catalysts can be processed to form a suitable suspension and subsequently this can be applied to the desired non-porous surfaces. As set out above, this can be done by soaking in a suspension of a commercial catalyst, by spraying a suspension of such a catalyst or through electrophoretic coverage starting from a commercial catalyst.

With each of these methods, however, it remains cumbersome to apply a properly bonding layer of a reasonably uniform thickness to a relatively large metal surface. For instance, the adhesion between the aluminum oxide crystallites grown from the alloy and the catalyst material is not strong. Furthermore, an essential drawback of alloys, such as Fecralloy or Kanthaal, is that such alloys cannot be properly welded due to the aluminum oxide layer present on the surface. Moreover, such alloys are difficult to bring into a desired form.

In the International patent application WO 01/96234 A2 it has been proposed to apply catalytically active layer to metallic substrates by sputtering. To accomplish a proper adhesion, the starting material is an alloy containing iron, chromium, aluminum and yttrium. Beforehand, these alloys are heated in air at 1100° C. for 50 hours. This leads to formation of aluminum oxide or chromium oxide crystallites on the alloy surface. Thereafter, the thus pretreated alloy surface is covered with a layer of metallic magnesium and nickel. This is done by sputtering, whereby the metal is atomized by argon ions incident on that metal, which ions have been formed in a glow discharge in argon of a low pressure.

According to the method of the International patent application WO 01/96234 A2, magnesium and nickel are atomized simultaneously. To obtain a uniform composition, the metal surface to be covered is spun at 10 rpm. Evidently, this is possible only with relatively small substrates. The method described in the International patent application WO 01/96234 A2 covers perforated alloy discs of a diameter of only 13 mm. For covering larger metal or alloy surfaces, the method of the International patent application WO 01/96234 A2 is therefore less suitable.

The method of the International patent application WO 01/96234 A2 leads to the application of a layer of metallic nickel and magnesium atoms to the surface of the thermally pretreated alloy. Such a layer is not suitable as a catalyst, since the porosity of the layer is very low and hence the exposed catalytically active surface is also small. When a second catalytically active component is applied to the nickel-magnesium layer, such as the rhodium that is applied in a second preparation step according to the method of the International patent application WO 01/96234 A2, this second component will not expose any large surface either. Therefore, according to the method of the International patent application WO 01/96234 A2, the magnesium and nickel are oxidized by heating the covered alloy surface in air or oxygen. Heating is done at temperatures of from 800 to 1000° C. and preferably at 900° C. Heating is done for 2 to 6 hours, preferably for 4 hours.

It will be clear that the adhesion of the nickel and magnesium containing layer is adversely affected by the oxidation. As a result of the oxidation, the volume of the layer increases, so that the layer applied is subject to tension. Also, the porosity of such a layer will be low. For that reason, to raise the porosity of the layer, according to the method of the International patent application WO 01/96234 A2, the nickel oxide in the layer is reduced by heating in a hydrogen containing stream at 900° C. for 4 hours. In that case, the nickel oxide alone is reduced, while the magnesium oxide does not react. According to the method of International patent application WO 01/96234 A2, the catalytically most active component, the rhodium, is then applied, by sputtering, onto the layer obtained after reduction of the nickel oxide. It will be clear that in this way the catalytically most active component cannot be provided deeply into the pores of the porous layer obtained by reduction of the nickel oxide-magnesium oxide.

The method according to the International patent application WO 01/96234 A2 accordingly has the following drawbacks. The desired configuration of a catalytically active component on a porous carrier can only be effected by first oxidizing the primarily applied mixture of a base and a less base metal and then reducing the less base metal oxide. It is clear that in this way the porous structure of the layer as applied cannot be properly set. Also, the distribution of a catalytically more active component to be subsequently applied is difficult to control according to the method of the International patent application WO 01/96234 A2. In addition, with this method, it is not possible to manufacture catalysts according to an in-line process. Therefore, this method is comparatively little attractive from a commercial viewpoint. Moreover, during the manufacture of catalysts according to this method, a relatively large part of the catalyst material is lost in that only a small part of the material in effect contacts the substrates and subsequently remains behind on the substrate. Therefore the known method is costly and environmentally harmful.

If one were to use the method of DE-A-196 10 015 for manufacturing a catalyst, for which DE-A-196 10 015 does not give any hint, it would not be easy to deposit the at least two components of a technical catalyst system, namely the carrier and the active component, on the substrate with a uniform structure and composition. This because of the fact that in DE-A-196 10 015 the material to be applied on the substrate is supplied as solid particles to the plasma through a narrow pipe. It will be clear that a very regular supply of solid particles to the plasma is difficult to realize in this manner.

Contrary to the patent application of Hoechst A. G. discussed above, EP 1034 834 of Sulzer Metco A. G. particularly aims at the application of catalytically active layers on metallic surfaces. To cover a large surface, the plasma is generated at low pressure. Moreover, to increase the surface covered, the plasma source is swiveled. Although a large surface can be covered in this manner, the density of the plasma is such that only very thin layers can be applied. In the method according to the patent application EP 1 034 843 of Sulzer Metco A. G., a uniform gas pressure of 15 to 1500 Pa is used, and preferably a pressure of 100 to 500 Pa. In the method according to the patent application no. 1020923 of O.T.B., a pressure lower than 60 mbar (5×10⁴Pa) and preferably lower than 5 mbar. (5×10³ Pa) is used in the processing chamber, as stated in column 1, lines 46 to 48. The gas pressure according to the method of Sulzer Metco A. G. is so low, that it only results in a low deposition rate. As is reported in column 2, lines 23 to 25, such low gas pressures result in plasma flames with a length of for instance, 2.5 m.

According to the laid-open patent application EP 1 034 843 of Sulzer Metco A. G., a flow of solid particles is introduced in the strongly diluted plasma flame through a carrier gas. In the patent application, it is stated that the plasma flame effects a homogenous dispersion of the solid particles in the flame. This dispersion enables the application on the substrate of very thin layers having a uniform thickness. In the laid-open patent application EP 1 034 843 of Sulzer Metco A. G., the aim is to apply porous layers. They say that they achieve this by using powders with particles of an average diameter of less than 5 μm. Since in the diluted plasma flame such particles only partly melt, a porous layer is created. If we ignore the contact surface between the particles, particles having a diameter of less than 5 μm of aluminum oxide (density 3.6 g/cm³) result in a surface of 3.3 m² per gram. It is questionable whether a very thin porous layer with a specific surface of a maximum of 3.6 m²per gram will yield a sufficiently high catalytic activity per volume unit. In column 3, lines 54 and 55, it is remarked that a large number of very thin layers can successively be deposited on the substrate. The first weak point of the method according to the laid-open patent application EP 1 034 843 of Sulzer Metco A. G. is that thicker porous layers are required for a usable catalytic activity. Only by depositing a large number of very thin layers on top of each other, thicker porous layers can be realized. According to lines 56 and 57 of column 3, their aim is a final layer thickness of 10 μm. According to lines 8 and 9 of column 4, in each deposition step, layers of 0.1 to 0.5 μm can be deposited. Thus, this requires the successive application of 20 to 100 layers on the substrate. Of course, this is technically laborious. The second weak point of the laid-open patent application EP 1 034 843 of Sulzer Metco A. G. is the introduction of the powder or the mixture of powder into the plasma flame by means of a gas flow through a pipe. Porous materials, such as aluminum oxide used as carrier material for catalysts, generally contain much absorbed material which desorbs very fast when the pressure is lowered. Fine particles of porous material will often spontaneously fluidize when evacuated through the desorbing gas. In the evacuation of powders, for instance for determining the accessible surface by physical adsorption of nitrogen, this unpleasant phenomenon is well known to a skilled person. Dosing carrier materials as powder through a pipe into a processing chamber maintained at a low pressure can give rise to great problems due to the stormy desorption of adsorbed gas.

In the method according to the PCT application WO 01/32949 of Agrodyn Hochspannungstechnik GmbH and Fraunhofer-Gesellschaft zur Förderung der angewandten Forschung, a plasma arc generated using an AC voltage is used. The applicants consider the introduction of the substrate into an evacuated processing chamber difficult to carry out in a continuous manner and therefore have as their object to describe a process which can be carried out at atmospheric pressure. In the application, it is stated that it is part of the state of the art to generate a plasma by letting a corona discharge take place at atmospheric pressure. It is also part of the state of the art to introduce into the plasma a gaseous precursor of the material to be applied and to realize deposition of the desired material in this manner. In this manner, however, only deposition rates of 10 to 20 μm per second (page 1, line 32) are achieved. Furthermore, the plasma is only formed in a small zone between the source and the workpiece, enabling one to operate only when the distances between the plasma source and the workpiece are short. According to this known method, the corona discharge generating the plasma is not to take place in a stationary gas atmosphere, but in a gas flow. The plasma flow thus obtained is directed to the surface to be covered, so the counter electrode no longer needs to be provided below the substrate (page 2, lines 20 to 22). A gaseous precursor of the material to be applied is supplied into the plasma flow relatively close to the surface to be covered. In this manner, premature emptying of the precursor is prevented (page 2, lines 22 to 31).

A drawback of the method according to the PCT application WO 01/32949 of Agrodyn Hochspannungstechnik GmbH and Fraunhofer-Gesellschaft zur Förderung der angewandten Forschung is the small surface covered by the plasma beam. Also, of by no means all carrier materials and catalytically active materials gaseous compounds having a sufficiently high vapor pressure are available. The applicants are of the opinion that solid particles can also be supplied to the plasma flow; according to lines 21 to 24 of page 3, solid substances or liquids can be supplied to the plasma flow, which sublimate or vaporize in the plasma flow. However, for, for instance, carrier materials such as aluminum oxide and zirconium dioxide, sublimating or vaporizing is very difficult to realize. Moreover, according to the method of WO 01/32949, an AC voltage is used to generate the plasma flow. The atmospheric pressure at which the process is carried out and the AC voltage source form a clear distinction from the method according to the invention to be described hereinafter.

The publication of Pascal Brault (Ann.Chim.Sci.Mat. 2001, 26 (4) pp. 69-77) mentions a deposition process in which an AC voltage is used. The authors sputter palladium from a palladium spiral on a non-porous substrate. Such a thin layer of metal is generally not suitable for technically performed catalytic processes, since the surface is not sufficiently large. At (very) high temperatures, a thin non-porous layer of precious metal would be able to produce a sufficiently high activity. At (very) high temperatures, however, the thin layer will quickly break up and sinter to relatively large metal particles having a surface that is too small.

The object of the present invention is to eliminate the disadvantages of the known methods while maintaining the advantages thereof. In particular, the invention contemplates a method of applying preferably porous, properly bonding catalyst layers of a uniform, properly settable chemical composition, to substrates.

According to the invention, to that end, the method is characterized by the features of claim 1.

It has been found that in this way, the deposition material is applied to the substrate relatively uniformly, in a properly controllable manner. As the first and the second material are deposited, preferably simultaneously, on the substrate in a particular ratio, a homogeneous, fine and preferably porous distribution of the catalyst material is obtained in the catalyst layer deposited, while this catalyst layer possesses particular desired chemical properties. Moreover, in this way, a good porosity of the deposited material can be obtained. The plasma flowing from the cascade source normally has a relatively high outflow velocity, so that the plasma can be accurately aimed at the substrate to deposit the deposition material thereon. To that end, the pressure in the processing chamber can be kept relatively low with respect to the pressure in each cascade source. Further, for instance by the plasma and/or a suitable electrical field, ions formed in the plasma can be accelerated to a surface of the substrate to be covered, for the purpose of the deposition on that substrate. Of importance is that with the method according to the invention, a non-porous or porous layer of a uniform pore structure and a uniform chemical composition can be applied to a relatively large surface. Per source, therefore, a relatively large surface can be covered. According to the method, this is achieved by making use of a cascade source, that is, a direct current source, whereby the gas pressure in the processing chamber is kept relatively low with respect to the gas pressure in the cascade source or, when several cascade sources are used, with respect to the gas pressure in the cascade sources. As a result, the plasma expands, so that the plasma can cover a relatively large surface.

With the method according to the invention, catalysts can be manufactured that are intended for various purposes. The many advantageous possibilities of use include, for instance, porous catalysts that are used in a Fischer-Tropsch synthesis to form long synthetic chains from small hydrocarbons, such as methane. Other examples of possible uses have been mentioned hereinabove.

The deposition material referred to preferably comprises at least one catalyst material which, whether or not after an activation treatment such as a reducing step, is catalytically active. The distribution of the catalytically active component over the surface of the substrate can be properly controlled by the use of the method according to the invention. Examples of catalytically active elements are nickel, copper, platinum and palladium. In addition, the deposition material can comprise, for instance, at least one carrier material, which material is inherently, or after a further treatment, suitable to carry the catalyst material. The carrier material can comprise, for instance, a metal oxide or semiconductor oxide which is directly suitable for carrying the catalytically active material. In addition, the carrier material to be deposited can comprise a metal or semiconductor, which material acquires desired carrier properties only after an oxidation step. The chemical composition of the material deposited on the substrates is properly settable owing to the use of the method according to the invention.

Surprisingly, properly bonding layers of carrier materials can be applied to solid substrate surfaces with the embodiment according to the invention, in particular to metal surfaces. The use of carrier materials such as titanium dioxide and zirconium dioxide, for instance, are attractive here, because these materials are stable to (strongly) alkaline solution.

Due to the plasma being generated by at least one plasma cascade source, a high deposition rate of the deposition material can be obtained. Moreover, the use of this source enables an in-line method for manufacturing catalysts. As a result, the catalysts can be produced in relatively large numbers at a high speed.

According to a further elaboration of the invention, the deposition material is supplied outside the at least one plasma source into the processing chamber, preferably to the plasma in the processing chamber.

What is thus avoided is that the deposition material can foul the source internally. To that end, for instance, at least one volatile compound of the deposition material can be supplied to the processing chamber for the purpose of the deposition. In this case, the chemical composition of the catalytically active layer can be properly controlled by setting the supply of the volatile compound of the catalytically active element. An example is a volatile aluminum compound and a precious metal compound, such as, for instance, a platinum compound. In the presence of a minor amount of water vapor or oxygen, the aluminum, either during the transport to the surface to be covered, or after application to the surface, can be oxidized to form aluminum oxide, which functions as carrier for the precious metal. By setting the vapor pressure of the gaseous compounds of the elements to be applied, the chemical composition of the layer to be applied can be controlled. The volatile compound can further contain a precursor material that can decompose in the material to be deposited. Some precursors disintegrate spontaneously in vacuum and can therefore be introduced outside the plasma into the processing chamber. Other precursors disintegrate only under the influence of the plasma and will therefore have to be supplied to the plasma.

According to an advantageous embodiment of the invention, at least one sputtering electrode which comprises the deposition material is set up in the processing chamber, while the plasma is brought into contact with each sputtering electrode to sputter the substrate with the material from the electrode.

In this way, the deposition material can be simply sputtered onto the substrate while maintaining the above-mentioned advantages. Preferably, the at least one sputtering electrode contains at least a part of both the at least one catalyst material and the carrier material to be deposited. By setting the weight ratio of the different materials in the electrode, the chemical composition of the catalytically active layer can be properly controlled. If necessary, it is even possible to start from a mixture of powders of the desired metals. An important distinction from the method according to the International patent application WO 01/96234 A2 is that in this case an oxidation of the metal atoms can take place during the transport by the gas phase or immediately upon incidence on the alloy surface to be covered.

Further, the at least one sputtering electrode can contain only carrier material. Thus, an electrode of aluminum oxide, silicon dioxide, titanium dioxide or zirconium dioxide can be employed. Evidently, the corresponding metal of the intended carrier can be used as electrode. The deposition of that material can then be done in an oxygen containing gas atmosphere. Because titanium dioxide and zirconium dioxide have very favorable properties as catalyst carrier, while it is difficult to process such carriers into suitably shaped bodies, this embodiment of the method according to the invention is very attractive. In this case, for instance, gaseous compounds of catalytically active components to be deposited can be passed into the plasma, for instance via supply channels provided in the electrode. After deposition, a thermal treatment at an elevated temperature in a hydrogen stream can then be carried out for the purpose of a selective reduction of the catalytically active element to the metal, while the carrier material is not reduced.

Especially when applying complex catalyst systems, such as exhaust gas catalysts, that contain a series of different metals and oxides, the methods according to the invention are very attractive. It is surprising that the method according to the invention can yield good porous layers, in which the catalytically active element(s) is or are properly accessible to reactants. Especially after reduction of possibly formed metal oxides to the corresponding metals, a very attractively structured layers is had.

It is surprising that according to the different embodiments of the method according to the invention, moreover, properly bonding, porous, catalytically active layers can be applied to metal or alloy surfaces. According to a special embodiment of the method according to the invention, therefore, catalytically active layers are applied to metal or alloy surfaces.

When the catalytically active component is a metal or alloy, a reducing treatment is generally necessary after the deposition on the solid surface. It has been found that the reduction can be carried out very well by heating the covered substrate in an atmosphere of a reducing gas. According to a preferred embodiment of the method according to the invention, this reduction is carried out at elevated temperature in a gas stream of a particular amount of hydrogen in an inert gas, such as nitrogen or argon.

According to a preferably applied mode of the method according to the invention, corrugated metal or alloy sheets are covered with a porous layer of, for instance, aluminum oxide, titanium dioxide or zirconium oxide, in which precious metals, such as platinum, palladium, and/or rhodium are included. Such sheets are subsequently processed into a form suitable to be used as exhaust gas catalyst.

The invention further relates to an apparatus which is characterized by the features of claim 34. With this apparatus, catalysts can be produced relatively fast and with a high uniformity over a large surface. The use of the plasma cascade source then offers the above-mentioned advantages.

Further elaborations of the invention are described in the dependent claims. The invention will now be explained with reference to two exemplary embodiments and the drawing, in which:

FIG. 1 shows a diagrammatic cross-sectional view of a first exemplary embodiment of an apparatus for manufacturing a catalyst;

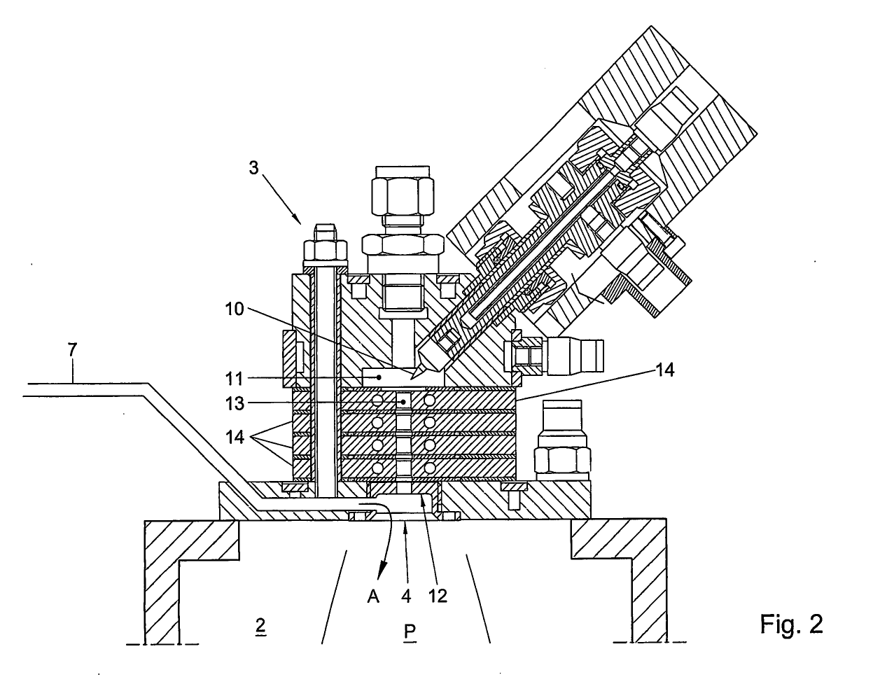

FIG. 2 shows a detail of the cross-sectional view shown in FIG. 1, in which the plasma cascade source is shown; and

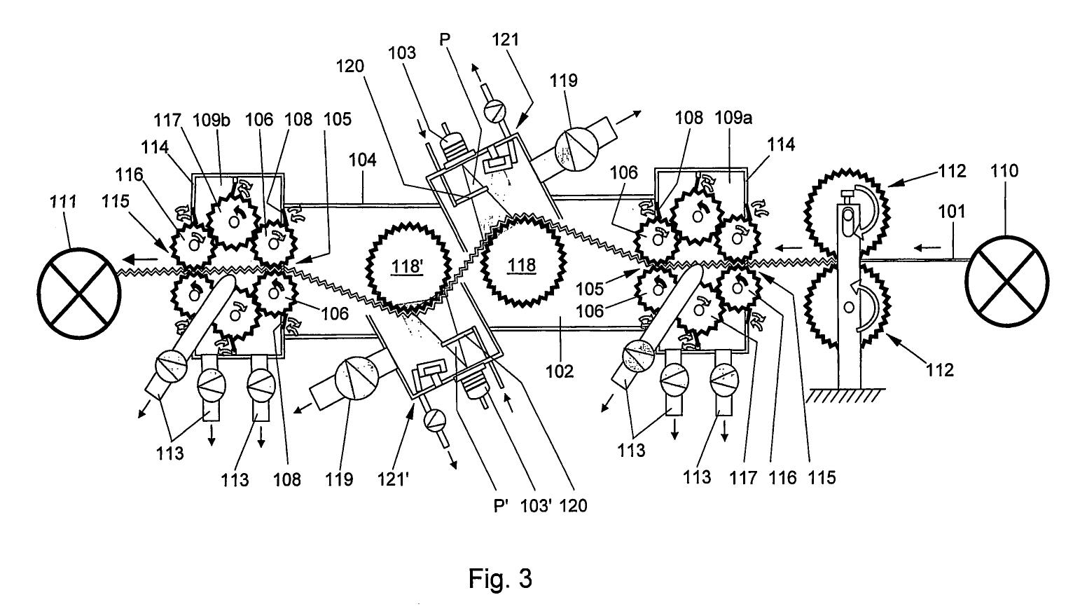

FIG. 3 shows a second exemplary embodiment of the invention.

FIGS. 1 and 2 show an apparatus for manufacturing a catalyst. The apparatus shown in FIGS. 1 and 2 is provided with a PECVD processing chamber 2 on which a DC (direct current) plasma cascade source 3 is provided. The DC plasma cascade source 3 is arranged to generate a plasma P with DC voltage. The apparatus is provided with a substrate holder 8 to hold one substrate 1 opposite an outlet opening 4 of the plasma source 3 in the processing chamber 2.

As shown in FIG. 2, the plasma cascade source 3 is provided with a cathode 10 that is present in a source chamber 11 and an anode 12 that is present at a side of the source 3 proximal to the processing chamber 2. Via a relatively narrow channel 13 and the plasma-outlet opening 4, the source chamber 11 opens into the processing chamber 2. The apparatus is dimensioned such that the distance L between the substrate 1 and the plasma outlet opening 4 is approximately 200 mm-300 mm. In this manner, the apparatus can have a relatively compact design. The channel 13 is bounded by the mutually electrically insulated cascade plates 14 and the anode 12. During the treatment of a substrate, the processing chamber 2 is maintained at a relatively low pressure, in particular lower than 50 mbar, and preferably lower than 5 mbar. Naturally, inter alia the treatment pressure and the dimensions of the processing chamber should be such that deposition can still take place. In practice, the treatment pressure for a processing chamber of the present exemplary embodiment has been found to be at least approximately 0.1 mbar for this purpose. The pumping means needed to obtain the treatment pressure are not shown in the drawing. Between the cathode 10 and anode 12 of the source 3, a plasma is generated, for instance by ignition of an inert gas, such as argon, which is present therebetween. When the plasma has been generated in the source 3, the pressure in the source chamber 11 is higher than the pressure in the processing chamber 2. This pressure can be, for instance, substantially atmospheric and be in the range of 0.5-1.5 bar. Because the pressure in the processing chamber 2 is considerably lower than the pressure in the source chamber 11, a part of the generated plasma P expands such that it extends through a relatively narrow channel 7, from the outlet opening 4, into the processing chamber 2 to make contact with the surface of the substrate 1.

The apparatus is provided with a gas supply channel 7 to supply a flow of a gas A to the plasma P in the anode plate 12 of the source 3. The gas A can, for instance, comprise a catalyst material to be deposited. The apparatus further comprises a sputtering electrode 6 arranged in the processing chamber 2. In the figure, the sputtering electrode 6 is arranged at a distance from the cascade source 3. However, this cathode 6 can also be present near the cascade source 3 or abuts this source 3. The sputtering electrode 6 contains at least one material B to be sputtered on the substrate, for instance a carrier material. The sputtering electrode 6 is arranged such that, during use, the plasma P generated by the plasma source 3 sputters the material B from the sputtering electrode 6 on the substrate 1. For this purpose, the electrode 6 is designed as a cylindrical body with a concentric passage 9 through which, during use, the plasma P extends from the source 3 to the substrate 1. For the purpose of sputtering, during use, the electrode 6 can be put under such pressure that the plasma ions strike the electrode 6 and eject the electrode material B. In addition, plasma ions can spontaneously strike the electrode 6 because of an inherently high kinetic energy of those ions of the expanding plasma P. In the present exemplary embodiment, the sputtering electrode 6 and the gas supply channel 7 are shown as being separate from each other. In addition, the gas supply channel 7 and the sputtering electrode can, for instance, be designed in an integrated manner to supply the materials A and B at substantially the same location to the plasma P.

During use of the exemplary embodiment shown in FIGS. 1 and 2, the materials A and B are deposited on the substrate 1 arranged in processing chamber 2. The material A supplied by the channel 7 is carried along by the plasma P flowing from the source 3 and deposited on the substrate 1. The material B from the electrode 6 is simultaneously supplied to the substrate 1 by sputtering. This method makes it possible to apply a catalyst layer, containing the materials A and B, on the substrate 1 in a very uniform manner. Since the plasma cascade source operates under DC voltage to generate the plasma, the catalyst layer can simply, substantially without adjustment during deposition, be grown at a constant growth rate. This is advantageous over use of a HF plasma source, where continual adjustment is usually required. Furthermore, with a DC plasma cascade source, a relatively high deposition rate can be achieved. During the deposition of the materials A, B, to the substrate 1 a specific electric potential can further be applied, such as by DC, pulsed DC and/or RF biasing, for instance for further promoting homogeneity of the deposition. In addition, the substrate 1 can be heated to a specific treatment temperature using heating means (not shown) known from practice. The temperature of the substrate affects the porosity of the layer to be applied. By choosing a specific temperature of the substrate, a desired porosity can thus be obtained.

FIG. 3 shows a second exemplary embodiment of an apparatus for manufacturing a catalyst. The second exemplary embodiment is arranged to deposit catalyst material and carrier material inline on a substrate web in the form of a long, sheet-shaped substrate 101 which can be rolled up. This apparatus is provided with a substrate supply roller 110 on which the substrate sheet 101 is wound. The supply roller 110 is arranged to supply the sheet 101 to a processing chamber 102 during use. The apparatus further comprises a discharge roller to discharge the substrate 101 which can be rolled up from the processing chamber 102. Between the supply roller 110 and the processing chamber 102, a pair of cooperating rollers 112 are arranged deform the substrate 101 unrolled from the supply roller 110. The cooperating outer circumferences of the rollers 112, engaging the substrate 101, are provided with engaging teeth, such that the rollers 112 serrate the sheet 101 during use.

The second exemplary embodiment is provided with two pre-chambers 109 arranged on both sides of the processing chamber 102. The processing chamber 102 is separated from the pre-chambers 109 by a wall 104. The wall 104 of the processing chamber 102 is provided with passages 105 for transport of the substrate sheet 101 between the processing chamber 102 and the pre-chambers 109. In each passage 105, two inner feed-through serration rollers 106, the outer circumferences of which are provided with teeth engaging the serrations of the sheet 101. The wall 104 of the chamber 102 is provided with swiveling closing flaps 108 extending to the inner feed-through serration rollers 106 to obtain a good connection between those serration rollers 106 and the cell wall 104. Each pre-chamber 109 is provided with pumping means 113 to maintain that chamber 109 at a relatively low pressure. An outer wall 114 of each pre-chamber 109 is also provided with a passage 115 to transport the substrate sheet 101 into and out of that pre-chamber 109 from and to an environment, respectively. In each of the passages 115, two outer feed-through serration rollers 116 arranged opposite each other are arranged, of which the outer circumferences engage the serrations of the substrate. Each pre-chamber 109 is further provided with closing flaps 108 to obtain a good connection between these external feed-through serration rollers 116 and chamber outer wall 114. Finally, in each pre-chamber 109, intermediate serration rollers 117 are arranged, which mechanically couple the outer feed-through rollers 116 to the inner feed-through rollers 106. The transportation passage provided by the feed-through rollers to introduce the sheet 101 from an environment into the processing chamber 102 and vice versa relatively tightly connects to the sheet 101, so that little environmental air can reach the processing chamber 102. In this manner, the pressure in the processing chamber 102 can be maintained relatively low compared to an environmental pressure.

The processing chamber 102 is provided with two plasma cascade sources 103, 108′ arranged to generate two plasmas P, P′. Moreover, the cascade sources are arranged such that, during use, these sources 103,103′ are directed to substrate surfaces remote from each other of the substrate 101 supplied into the processing chamber 102 to be able to bring both substrate surfaces into contact with plasma P, P′. Near each plasma source 103, 103′, a gas shower head 120 is arranged in the processing chamber 102 to supply a material to be deposited to the respective plasmas P, P′. Furthermore, near each plasma cascade source 103, 103, a separate sputtering source 121, 121′ is arranged to deposit material on the substrate 101 through a sputtering process. The processing chamber 102 further comprises pumping means 119 to maintain that chamber at a desired, low pressure.

In the processing chamber 102, opposite each plasma source 103, 103′, a heatable substrate positioning roller 118, 118′ is arranged to lead the substrate 101 supplied into the processing chamber 102 along the respective plasma source P, P′ and to bring to and/or maintain at a desired processing temperature. The arrangement of the positioning of the positioning rollers 118, 118′ and the plasma sources 103, 103′ allows material to be deposited on both sides of the substrate sheet 101 in the processing chamber 102.

During use of the second exemplary embodiment, the substrate sheet 101 is supplied by the supply roller 110 to the roller pair 112. The sheet 101 is then provided with serrations by this roller pair 112. Next, the sheet 101 is introduced into the processing chamber 102 through the pre-chamber 109a shown on the right in the FIG. 3. In the processing chamber 102, catalyst material and carrier material are deposited on the one side of the serrated sheet 101 near the one positioning roller 118. Deposition of the catalyst material preferably takes place under the influence of the plasma P of the one plasma cascade source 103. In this manner, a high uniformity and an optionally good porosity of the deposited catalyst layer can be obtained The sputtering source 121 can simultaneously deposit carrier material on the substrate sheet 101. Deposition of material by the plasma source 103 and the sputtering source 121 can simply be adapted to each other in order to obtain desired chemical and morphological properties of the catalyst layer.

After deposition of material on the one side, the other side of the substrate sheet 101 is treated in a similar manner by the other plasma source 103′ and sputtering source 121′ in order to deposit a catalyst layer on that side. During the treatment of the sheet 101, the positioning rollers 118, 118′ can be brought to a desired treatment temperature by heating means (not shown), so that the sheet obtains a desired deposition temperature. After the treatment, the sheet 101 is discharged from the processing chamber 102 through the left pre-chamber 109b and rolled up on the discharge roll 111.

The second exemplary embodiment can be used to manufacture a catalyst according to an in-line process, which is very attractive from a commercial point of view. In addition, the composition of the catalyst can be controlled well. Advantages of use of the cascade sources 103, 103′ have already been discussed above. The serrated sheet 101 provided with catalyst material can simply be processed further to serve as a catalyst. For instance, parts of the sheet 101 can simply be folded to compact proportions, for instance to cylindrical catalyst reactors.

It is evident that the invention is not limited to the exemplary embodiments described. Various modifications are possible within the scope of the invention as worded in the hereinafter following claims.

For instance, the substrate can comprise carrier material, such as an oxidized metal and/or oxidized semi-conductor, for instance aluminum oxide, silicon dioxide, titanium dioxide and/or zirconium dioxide. In addition, the substrate can comprise a material which is oxidizable to a carrier material. In this last case, the deposition can be carried out in an environment containing oxygen for the oxidation of the substrate material.

In addition, the sputtering electrode can, for instance, be provided with fluid supply channels to introduce into the plasma said volatile compounds of catalytically active components to be applied.

The sputtering cathode can further be designed in various manners, and comprise, for instance, a planar, tubular, U-shaped cathode or be designed in a combination of this or other cathode forms.

The carrier material to be deposited can further be the same as the material of the substrate or differ therefrom.

Further, a volatile compound can be introduced in the processing chamber to be deposited on the substrate. Moreover, such a volatile compound can contain at least one precursor material which decomposes in the material to be deposited before the material has reached the substrate. Decomposition of that material can occur, for instance, spontaneously and/or under the influence of a plasma. Examples of precursor materials are platinum, TPT and TEOS.

Furthermore, the deposition material can be deposited such that the chemical composition of the material deposited measured over distances of 5 cm, preferably over a distance of 10 cm, more in particular over a distance of 20 cm, differs less than 10%, in particular less than 5% and more in particular less than 1%. In this manner, a catalyst layer with a very homogenous composition can be obtained.

Further, different types of substrates of different forms can be used, for instance hard and/or porous substrates of various materials.

Furthermore, various methods can be used to clean a sputtering cathode before and after use, for instance by now and then reversing the polarity of the cathode using a suitable electric tension.

In addition, the apparatus can be provided with at least one second source, such as a plasma source, plasma cascade source, vapor deposition source or sputtering source 121 to deposit the material on the substrate 101. In this manner, the at least one catalyst material A and the at least one carrier material B can, for instance, be deposited on the substrate 101 by separate sources, one of these sources being the plasma cascade source 103, while the other source is, for instance, a plasma source, plasma cascade source, vapor deposition source and/or sputtering source 121. The optional plasma used for the second source can be generated using a DC, RF or ECR source. Furthermore, the shape of the cathode of the source is not limited to a pointed shape, linear and planar cathodes are also possible. In this manner, the geometry of the plasma can be adapted to the geometry of the substrate to be treated.

When the carrier material comprises an oxidic material, which usually has a poor thermal conduction, it is advantageous if the carrier material also comprises at least one thermally conductive material. In this manner, the thermal conduction of the catalyst can be increased, which is desired in specific catalyst applications to prevent overheating of the catalyst. The thermally conductive material can comprise various suitable materials, for instance carbon. The thermally conductive part of the carrier material can simply be applied during the manufacture of the catalyst by means of one the methods described.

1. A method for depositing a layer on a substrate, comprising:
introducing a substrate is introduced into a processing chamber;
generating at least one plasma by at least one plasma cascade source;
depositing at least one deposition material on the substrate under the influence of the plasma; and
manufacturing a catalyst layer by depositing at least a second deposition material on the substrate by at least a second plasma cascade source, a plasma source, a vapor deposition source and/or a sputtering sources.

2. A method according to claim 1, wherein said deposition material is supplied outside the at least one plasma source into the processing chamber, such as to the plasma in the processing chamber.

3. A method according to claim 1, wherein at least one volatile compound of said deposition material is supplied to the plasma for the deposition.

4. A method according to claim 3, wherein the volatile compound contains at least one precursor material which decomposes in the processing chamber in material to be deposited, before the material has reached the substrate.

5. A method according to claim 1, wherein at least one sputtering electrode which comprises said deposition material is arranged in the processing chamber, and the plasma is contacted with each sputtering electrode to sputter the substrate with the material of the electrode.

6. A method according to claim 5, wherein the plasma is passed at least partly through at least one passage of the at least one sputtering electrode to contact the plasma with the electrode.

7. A method according to claim 1, wherein said deposition material comprises at least one catalyst material which, whether or not after an activation treatment such as reducing, is catalytically active.

8. A method according to claim 1, wherein said deposition material comprises at least one carrier material, which material is initially, or after a further treatment, suitable to carry catalyst material.

9. A method according to claim 8, wherein the at least one catalyst material and the at least one carrier material are deposited on the substrate by different sources.

10. A method according to claim 5, wherein the at least one sputtering electrode contains at least a part of both a catalyst material and a carrier material.

11. A method according to claim 10, wherein the sputtering electrode contains compressed powders of said catalyst and carrier materials to be deposited on the substrate.

12. A method according to claim 10, wherein the at least one sputtering electrode contains an alloy of said catalyst material and said carrier material.

13. A method according to claim 1, wherein the substrate comprises sheet material.

14. A method according to claim 1, wherein the substrate is moved in the processing chamber at least in such a way that each time a different part of the substrate makes contact with the plasma.

15. A method according to claim 1, wherein the substrate is brought from an environment into the processing chamber and is discharged from the processing chamber to the environment while the deposition material is deposited on the substrate in the processing chamber.

16. A method according to at least claim 1, wherein the substrate is substantially non-porous.

17. A method according to claim 1, wherein the substrate comprises at least one carrier material.

18. A method according to claim 1, wherein the substrate comprises at least one metal and/or alloy.

19. A method according to claim 1, wherein the substrate comprises Fecralloy.

20. A method according to claim 1, wherein the substrate comprises corrugated material.

21. A method according to claim 1, wherein the substrate is substantially porous.

22. A method according to claim 8, wherein said carrier material comprises a metal.

23. A method according to claim 8, wherein said carrier material comprises an oxidized metal.

24. A method according to claim 8, wherein said carrier material comprises a semiconductor.

25. A method according to claim 8, wherein said carrier material comprises an oxidized semiconductor.

26. A method according to claim 23, wherein the carrier material further contains a heat-conducting material.

27. A method according to claim 7, wherein the at least one catalyst material comprises nickel, copper, palladium, rhodium, platinum or iron or any combination thereof.

28. A method according to claim 7, wherein the deposition material is deposited such that the chemical composition of the deposited material measured over a distance 20 cm, and differs by less than 10%.

29. A method according to claim 1, wherein reducing is carried out at an elevated temperature for the purpose of reduction of the deposition material deposited on the substrate.

30. A method according to claim 29, wherein the reducing is carried out under the influence of hydrogen.

31. A method according to claim 30, wherein an inert gas which contains hydrogen is supplied to the substrate for the purpose of the reduction.

32. A method according to claim 1, wherein the substrate is adjusted to a particular electrical potential by DC, pulsed DC and/or RF biasing.

33. A method according to claim 1, wherein the substrate is adjusted to a treatment temperature.

34. An apparatus for depositing a layer on a substrate comprising:
at least one plasma cascade source to generate at least one plasma;
a first deposition material source configured to bring a first deposition material into each plasma;
a substrate positioner to bring and/or keep at least a part of a substrate in such a position in a processing chamber that the substrate makes contact with said plasma; and
a second plasma cascade source, a plasma source, a vapor deposition source and/or a sputtering source configured to deposit at least a second deposition material on the substrate.

35. An apparatus according to claim 34, wherein the first deposition material source comprises with at least one sputtering electrode which contains deposition material to be deposited, wherein the sputtering electrode is positioned such that the plasma generated by the at least one plasma source during use sputters material from the sputtering electrode on the substrate.

36. An apparatus according to claim 35, wherein each sputtering electrode is arranged downstream of the at least one plasma source, and at least one sputtering electrode is provided with at least one plasma passage to allow the plasma to pass from the source to the substrate.

37. An apparatus according to claim 35, wherein the sputtering electrode lies against the source.

38. An apparatus according to claim 37, wherein the first deposition material source comprises at least one fluid supply channel to supply a material to be deposited, being in a volatile state, to the plasma.

39. An apparatus according to claim 38, wherein the at least one sputtering electrode is provided with said fluid supply channel.

40. An apparatus according to claim 34, wherein the apparatus is provided with at least two plasma cascade sources to generate at least two plasmas, wherein these plasma cascade sources and the substrate positioning means positioner are positioned such that opposite sides of the substrate during use make contact with the plasmas generated by the two plasma cascade sources to deposit material an the opposite sides of the substrate.

41. An apparatus according to claim 34, wherein the apparatus is provided with a substrate supply roller and a discharge roller, respectively, to supply and discharge, respectively, a substrate that can be rolled up, such as a web and/or sheet-like substrate, to and from the processing chamber, respectively.

42. An apparatus according to claim 34, wherein a wall of the processing chamber is provided with at least one passage to pass the substrate into and/or out of that chamber.

43. An apparatus according to claim 42, wherein at least a part of the at least one passage of the processing chamber wall is bounded by oppositely arranged feed-through rollers, and the feed-through rollers are arranged to engage a part of the substrate disposed between them during use, for the purpose of feed-through of the substrate.

44. An apparatus according to claim 41, wherein the apparatus is provided with a pair of rollers to deform the substrate which has unrolled from the supply roller.

45. An apparatus according to claim 44, wherein the pair of rollers are arranged to corrugate and/or serrate the substrate.

46. An apparatus according to claim 34, wherein the apparatus is provided with a vapor deposition apparatus to vapor deposit material on the substrate.

47. An apparatus according to claim 34, wherein the apparatus is provided with at least one separate sputtering source configured to sputter material on the substrate.

48. A catalyst provided with at least one carrier material and at least one catalyst material, the carrier material comprising are oxidic material, and the carrier material further comprising at least one heat conducting material.

49. A catalyst according to claim 48, wherein the heat-conducting material comprises carbon.

50. A catalyst manufactured according to the method according to any of claim 1.
